(19) United States
(12) Patent Application Publication
(10) Pub. No.: US 2008/0153219 A1
(43) Pub. Date: Jun. 26, 2008

(54) Method for Manufacturing CMOS Image Sensor

(76) Inventor: Ji Hwan Yu, Yongin-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,960

(22) Filed: Oct. 30, 2007

(30) Foreign Application Priority Data
Dec. 26, 2006 (KR) 10-2006-0133461

(51) Int. Cl. H01L 21/336; H01L 21/425

(52) U.S. Cl. 438/197; 438/659; 257/E21.473; 257/E21.409

(57) ABSTRACT

A method for manufacturing a CMOS image sensor is provided. A metal line can be formed over a semiconductor substrate including a transistor structure. Dangling bonding on the surface of the semiconductor substrate can be removed after forming the metal line by injecting a preset amount of hydrogen (H) atoms on the surface of the semiconductor substrate. Then, a thermal treatment can be performed on the resulting structure.

### CROSS-REFERENCE TO RELATED APPLICATION

The present application claims the benefit under 35 U.S. C. §119 of Korean Patent Application No. 10-2006-0133461, filed on Dec. 26, 2006, which is hereby incorporated by reference in its entirety.

### BACKGROUND

Image sensors are devices that convert an optical signal into an electric signal. Image sensors may be classified into complementary metal-oxide semiconductor (CMOS) image sensors and charge coupled device (CCD) image sensors. Compared with CMOS image sensors, CCD image sensors have good characteristics in view of sensitivity and noise, but have difficulty in realizing high integration and have high power consumption. On the contrary, CMOS image sensors have advantages over CCD image sensors in that their manufacturing processes are simple and they are suitable for high integration and have low power consumption.

A CMOS image sensor is divided into a light receiving element region and a CMOS element region. A photodiode (PD) and a transistor are typically formed in the light receiving element region and the CMOS element region in a semiconductor substrate, respectively.

A monocrystalline silicon substrate is typically used as the semiconductor substrate. Silicon atoms that are not combined with hydrogen atoms exist on the surface of the silicon substrate. These silicon atoms form a dangling bonding on the surface of the substrate. This causes a current to flow even when a photodiode disposed in the light receiving element region does not receive light. This is called a dark current or dark defect.

In order to increase the reliability of CMOS image sensor, the dangling bonding occurring on the surface of the semiconductor substrate must be removed. However, the process of removing the dangling bonding is difficult to carry out.

### BRIEF SUMMARY

Embodiments of the present invention provide a method for manufacturing a CMOS image sensor, in which a dangling bonding is removed by injecting hydrogen atoms into the surface of a semiconductor substrate before performing a thermal treatment.

An embodiment of the present invention also provides a method for manufacturing a CMOS image sensor, in which a dangling bonding is further removed through an increase in a diffusion amount of H₂ gas by increasing a pressure of a process chamber so as to increase H₂ gas molecules within the process chamber for performing a thermal treatment.

In one embodiment, a method for manufacturing a CMOS image sensor includes: forming a metal line over a semiconductor substrate including a transistor structure; injecting a preset amount of hydrogen (H) atoms on the semiconductor substrate to remove dangling bonding; and performing a thermal treatment on the resulting structure.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of a CMOS image sensor for explaining a method for manufacturing a CMOS image sensor according to an embodiment of the present invention.

FIG. 2 is a flowchart illustrating a method for manufacturing a CMOS image sensor according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

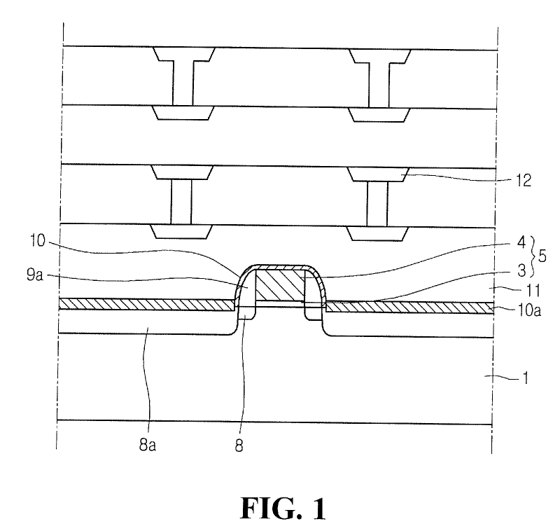

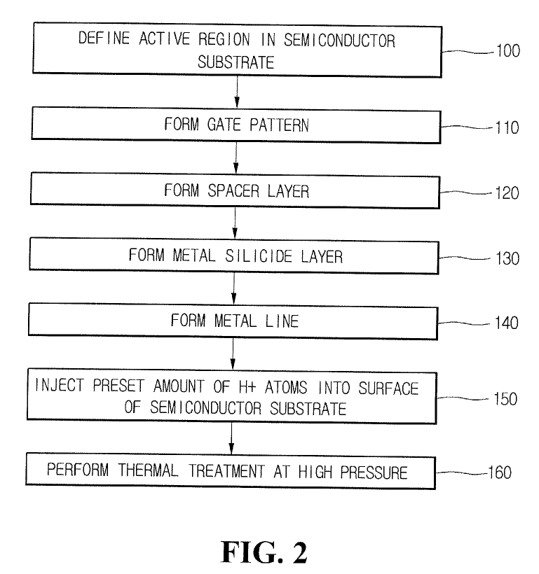

Referring to FIGS. 1 and 2, in process 100, a semiconductor substrate 1, for example a p-type semiconductor substrate, can be prepared, and a device isolation layer (not shown) can be formed on the p-type semiconductor substrate 1 to define an active region. In process 110, an oxide layer and a gate electrode layer can be sequentially formed over the semiconductor substrate 1 with the device isolation layer. The gate electrode layer and the oxide layer are sequentially patterned to form a gate pattern 5 in a CMOS element region. The gate pattern 5 can include a gate oxide layer 3 and a gate electrode 4 stacked on the semiconductor substrate 1.

In one embodiment, an n-type diffusion region can be formed in a photodiode region at an active region defined of a light receiving element region. A p-type diffusion region (not shown) can be formed in the photodiode region between the n-type diffusion region and the surface of the active region.

In process 120, a low-concentration impurity diffusion layer 8 can be formed in the active region at sides of the gate pattern 5. A spacer layer can be formed over the semiconductor substrate 1 having the low-concentration impurity diffusion layer 8. A selective isotropic etching can be performed on the spacer layer to form spacers 9a on sides of the gate pattern 5. In one embodiment, the spacer layer over a photodiode region can remain covering the photodiode.

In process 130, high-concentration impurity diffusion layers 8a can be formed in the active region at sides of the spacers 9a. A metal layer 10 can be formed over the semiconductor substrate 1 having the high-concentration impurity diffusion layers 8a. The metal layer 10 can be silicided to form a metal silicide layer 10a. The metal silicide layer 10a can be selectively formed on the surfaces of the high-concentration impurity diffusion layers 8a. The spacer layer can inhibit the metal silicide layer 10a from being formed over regions with the spacer layer, such as, for example, spacers 9a and photodiode regions (not shown). Unreacted metal 10 can be removed.

In process 140, a metal line can be formed. An interlayer dielectric layer 11 can be formed on the substrate having the metal silicide layer 10a, and a metal line 12 can be formed on the interlayer dielectric layer 11. Multiple metal lines 12 can be formed as needed. For example, three metal line layers can be formed. Metal lines 12 can be formed through any suitable metal line formation process. For example, a damascene process can be used.

In process 150 a dangling bonding can be removed by injecting a predetermined amount of hydrogen (H) atoms into the surface of the semiconductor substrate 1. In a further embodiment, in process 160, the process of removing the dangling bonding can be performed at a high pressure in a process chamber for performing a thermal treatment on the CMOS image sensor, such that the dangling bonding is removed by increasing a diffusion amount of H₂ gas.

The pressure inside the process chamber can be in the range of approximately 1 torr to approximately 10 torr. Further, after the injection of the hydrogen atoms, the thermal treatment may be performed at a temperature ranging from approximately 400° C. to approximately 450° C.

The process of removing the dangling bonding will be described below in more detail.

Processes 140 and 150 can be repeated for every metal layer in forming the metal lines 12 of the device. In process 140, a metal layer can be formed on the semiconductor substrate 1, and can be patterned to form the metal lines 12. In process 150, the dangling bonding can be removed by sufficiently injecting a preset amount of hydrogen (H) atoms into the surface of the semiconductor substrate 1.

At this point, hydrogen (H) atoms can be injected more accurately. This is advantageous to Si—H bonding. Consequently, the removal of the dangling bonding can reduce the dark current. The hydrogen gas can be mixed with nitrogen gas and then injected into the semiconductor substrate 1. The content of the hydrogen gas can be in the range of approximately 10% to approximately 30%.

In process 160, a thermal treatment using H₂ gas can be performed.

Because of side effects generated by increasing the temperature of the process chamber, the pressure can be increased instead. Molecular weight within the process chamber is determined by the ideal gas equation expressed as PV=nRT. Therefore, the value of n can be increased by increasing the pressure (P), not simply increasing an amount of gas.

Even though a large amount of gas flows, a large amount of gas is discharged when the pressure is constant. Therefore, the number of H₂ molecules within the process chamber is not increased. Consequently, the pressure should be increased in order to increase the number of the H₂ molecules.

The number of the H₂ molecules within the process chamber can be increased by increasing the pressure of the process chamber to approximately 1-10 torr. Accordingly, a diffusion amount of H₂ gas is increased, thereby reducing the dark current of the CMOS image sensor.

As described above, the dangling bonding can be removed by injecting hydrogen atoms as much as required into a surface of a semiconductor substrate before performing the thermal treatment. Furthermore, the dangling bonding can be further removed because of increase in the diffusion amount of H₂ gas by increasing the pressure of the process chamber so as to increase H₂ gas molecules within the process chamber for performing the thermal treatment.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a CMOS image sensor, comprising:
forming a metal line over a semiconductor substrate including a transistor structure; and
injecting a preset amount of hydrogen atoms on the surface of the semiconductor substrate having the metal line for removing a dangling bonding; and
performing a thermal treatment to the semiconductor substrate having the injected hydrogen atoms.

2. The method according to claim 1, wherein performing the thermal treatment comprises subjecting the semiconductor substrate to a high pressure within a process chamber for performing the thermal treatment, such that a diffusion amount of H₂ gas is increased.

3. The method according to claim 2, wherein the high pressure within the process chamber is in the range of approximately 1 torr to approximately 10 torr.

4. The method according to claim 1, wherein the thermal treatment is performed at a temperature ranging from approximately 400° C. to approximately 450° C. after the injecting of the hydrogen atoms.

5. The method according to claim 1, wherein injecting the hydrogen atoms comprises mixing hydrogen gas with nitrogen gas.

6. The method according to claim 5, wherein the content of the hydrogen gas is in the range of approximately 10% to approximately 30%.

7. The method according to claim 1, further comprising:
repeating the forming of a metal line and the injecting of a preset amount of hydrogen atoms at least once before performing the thermal treatment.

8. The method according to claim 1, further comprising:
defining an active region in the semiconductor substrate;
forming the transistor structure by forming a gate pattern on the active region of the semiconductor substrate, forming spacers on sides of the gate pattern, and forming source/drain regions in the semiconductor substrate; and
forming a metal silicide layer on the source/drain regions and the gate pattern.
